(19) United States
(12) Patent Application Publication
(10) Pub. No.: US 2024/0297492 A1
(43) Pub. Date: Sep. 5, 2024

(54) SEMICONDUCTOR FUSE WITH DETECTION CIRCUIT FOR THE DETECTION OF A DRIFT OF THE GATE THRESHOLD VOLTAGE

(71) Applicant: Lisa Dräxlmaier GmbH, Vilsbiburg (DE)

(72) Inventors: Stefan HOFINGER, Sankt Wolfgang (DE); Stefan HAGENAUER, Essenbach (DE)

(73) Assignee: Lisa Dräxlmaier GmbH, Vilsbiburg (DE)

(21) Appl. No.: 18/593,176

(22) Filed: Mar. 1, 2024

(30) Foreign Application Priority Data
Mar. 1, 2023 (DE) 10 2023 105 111.3

(51) Int. Cl. H02H 3/04; H02H 1/00; H02H 3/08

(52) U.S. Cl. CPC H02H 3/044; H02H 1/0007; H02H 3/08

(57) ABSTRACT

A semiconductor fuse for the disconnection of an electric consumer from an energy supply source for a battery-electric vehicle includes at least one semiconductor switching element connectable between the energy supply source and the electric consumer. The semiconductor switching element includes a gate control terminal to switch on and off a power path of the semiconductor switching element. The semiconductor fuse includes: a drive circuit that applies a drive voltage at the gate control terminal of the at least one semiconductor switching element; a detection circuit that determines a resistance of the power path of the at least one semiconductor switching element and, detects a drift of the gate threshold voltage based on the resistance of the power path; and a control system that indicates an issue with the at least one semiconductor switching element based on the detection of the drift of the gate threshold voltage.

### CROSS-REFERENCE TO RELATED APPLICATIONS

This application claims priority to and the benefit of German Application No. 10 2023 105 111.3 filed on Mar. 1, 2023. The disclosure of the above application is incorporated herein by reference.

### FIELD

The present disclosure relates to the field of electrical and electronic fuses for switching off overcurrents in battery-electric vehicles. In particular, the present disclosure relates to a semiconductor fuse with a detection circuit for the detection of a drift of the gate threshold voltage.

### BACKGROUND

The statements in this section merely provide background information related to the present disclosure and may not constitute prior art.

In the high voltage (HV) domain, in one example, in battery-electric vehicles, an electric fuse, for example a melting fuse, is used to switch off sustained overcurrents. Before a threshold current is reached, the melting fuse melts due to the associated heat development and switches off the current. Alternatively thereto, an electronic fuse with semiconductors can be used. In an electronic fuse, the overcurrent may be detected before the switch-off process can be started. For this purpose, the overcurrent that runs through the electric fuse element may be detected and evaluated. There are various methods to evaluate this which switch off based on the calculation of the line temperature or of the average current. However, it has been shown that such a switch-off is too slow, and the electronic fuse can be adversely impacted in the event of suddenly occurring short-circuit incidents.

### SUMMARY

This section provides a general summary of the disclosure and is not a comprehensive disclosure of its full scope or all of its features.

The present disclosure provides a concept for a switch-off of overcurrents in battery-electric vehicles, in which the above-mentioned disadvantages do not occur.

The present disclosure provides a semiconductor-based fuse or semiconductor fuse, also referred to in the following as digital fuse (“dFuse”), which detects threshold currents, such as, for example, short-circuit currents, and can disconnect them faster than circuit breakers, melting fuses, or pyrofuses. In order to provide disconnection with the semiconductor fuse according to ASIL B in the HV domain, diagnostics are desired for the semiconductor depending on the technology, such as, for example, SIC-MOSFET, IGBT, SI-MOSFET, etc. One such diagnosis is the gate threshold voltage drift detection via a detection circuit, as presented in this disclosure. This provides that undesired switching on is inhibited, or provides that a switching off is provided in the event of a short circuit.

The gate threshold voltage drift detection presented herein functions as follows. Before the main fuses, or, depending on the installation location of the dFuse, the second main fuse, unblocks the system, a voltage is applied at the control terminal (gate in the case of a MOSFET) that is lower than the typical gate threshold voltage, for example, 4V.

With the aid of the detection circuit (which also corresponds to a modified DESAT circuit), it is then checked whether the power path (drain-source) is high-resistance. This is the case when a voltage is detected at the measuring points TP1 or TP2 with the aid of a comparator (as shown in more detail in FIG. 3), which has approximately the value of V2 (see FIG. 3). If this is the case, then no drift has occurred, and the normal operation can be continued after this diagnosis. During further operation a switch-off is provided by this diagnosis. If the measuring point TP2 is used, a statement may be made whether the drain-source resistance is greater or less than R2 (see FIG. 3) (realization with a current source as shown in FIG. 3).

The gate threshold voltage drift detection presented here may be used in all types of electronic fuses, or dFuses, or semiconductor fuses, both in the low voltage (LV) domain and in the high voltage (HV) domain. With the gate threshold voltage drift detection described, here, an HV semiconductor fuse can be provided that fulfills the ASIL-B standards or higher for disconnection. Conventional products cannot fulfill these standards.

According to a first aspect, the present disclosure provides a semiconductor fuse for the disconnection of an electric consumer from an energy supply source for a battery-electric vehicle, in which the semiconductor fuse includes: at least one semiconductor switching element that can be connected between the energy supply source and the electric consumer, in which the at least one semiconductor switching element includes a gate control element for switching on and off a power path of the at least one semiconductor switching element in order to connect the electric consumer to the energy supply source or disconnect it from the energy supply source; a drive circuit that is configured to apply a drive voltage at the gate control terminal of the at least one semiconductor switching element, which drive voltage is lower than a prescribed gate threshold voltage of the at least one semiconductor switching element; a detection circuit that is configured to determine a resistance of the power path of the at least one semiconductor switching element, and based on the resistance of the power path to detect a drift of the gate threshold voltage; and a control system that is configured to indicate, in the event of a detection of the drift of the gate threshold voltage, an issue with the at least one semiconductor switching element.

In the event of a detection of a drift of the gate threshold voltage, the control system can thus diagnose an issue with the at least one semiconductor switching element, and quickly switch off the at least one semiconductor switching element so that it can be replaced.

Due to the gate threshold voltage drift detection, such a semiconductor fuse results in the diagnosis of whether the semiconductor switching element is still functional and can be switched off. The semiconductor fuse inhibits an undesired switch-on, or that a switch-off is provided in the event of a short circuit.

The semiconductor fuse can thus provide functions according to the ASIL standards.

In a field-effect transistor or MOSFET, the gate threshold voltage may be the gate voltage or gate source voltage at which an appreciable current flows in relation to the maximum drain current. The gate threshold voltage may be taken from data sheets of the transistors. In a field-effect transistor, the power path of the semiconductor switching element may be the path between drain and source terminal.

According to one form of the semiconductor fuse, the at least one semiconductor switching element includes a drain terminal and a source terminal, between which the power path of the at least one semiconductor switching element may be formed, in which the resistance of the power path corresponds to a resistance between the drain terminal and the source terminal.

This results in the resistance between the drain terminal and the source terminal being determined by voltage measurements, with the result that the gate threshold voltage drift detection may be carried out rapidly.

According to one form of the semiconductor fuse, the gate control terminal of the at least one semiconductor switching element includes a gate resistor, in which the drive circuit is configured to apply the drive voltage at the gate resistor of the gate control terminal; and in which the detection circuit is configured to determine the resistance of the power path depending on a gate voltage at the gate control terminal.

This results in that the drift of the gate threshold voltage may be synchronized by applying the drive voltage at the gate resistor, and thus the resistance of the power path can be determined.

According to one form of the semiconductor fuse, the detection circuit may be connected in parallel with the at least one semiconductor switching element, and configured to impress a current in the power path of the at least one semiconductor switching element.

This results in that via the current impressed in the power path, the resistance of the power path can be simply determined, and thus a drift of the gate threshold voltage can be efficiently detected.

According to one form of the semiconductor fuse, the detection circuit includes a detection resistor, and is configured to guide the current impressed in the power path of the at least one semiconductor switching element via the detection resistor.

This results in the detection resistor being used to provide measurement points for a voltage measurement, based on which the resistance of the power path may be determined, and thus a drift of the gate threshold voltage may be efficiently detected.

According to one form of the semiconductor fuse, the detection circuit includes a voltage source and a current source that are connected in series with the detection resistor, and are configured to impress the current in the power path.

This results in that a predeterminable current may be impressed in the power path.

According to one form of the semiconductor fuse, the detection circuit includes a voltage source and an auxiliary resistor that are connected in series with the detection resistor and configured to impress the current in the power path.

This results in that the above mentioned current source may be omitted, and instead the auxiliary resistor may be used in order to impress a predeterminable current in the power path. The detection circuit may thus be constructed in a simpler way.

According to one form of the semiconductor fuse, the detection circuit is configured to detect a voltage at a first terminal or a second terminal of the detection resistor, and based on the detected voltage determine whether the power path is high-resistance.

This results in that via such a voltage at one of the terminals of the detection resistor, the resistance of the power path may be determined.

According to one form of the semiconductor fuse, the detection circuit includes a comparator that is configured to compare the voltage at the first terminal or the second terminal of the detection resistor with a reference voltage.

This results in that the comparator offers a simple possibility to carry out a threshold value comparison. Depending on the result, a drift of the gate threshold voltage may be detected.

According to one form of the semiconductor fuse, the comparator is configured to set, based on a result of the comparison, a flag that indicates whether a drift of the gate threshold voltage is present or not present.

This results in that the comparator has a low latency, and the result is available quickly at its output, so that it is possible to rapidly detect whether a drift of the gate threshold voltage is present or not.

According to one form of the semiconductor fuse, the detection circuit is configured to indicate a presence of a drift of the gate threshold voltage when the voltage at the first terminal or the second terminal of the detection resistor is lower than the reference voltage.

This results in the detection circuit may indicate the presence of a drift of the gate threshold voltage to the control system, for example, via the flag at the output of the comparator. The control system can either query the flag or receive it via a control input and thus quickly react to the presence of a drift of the gate threshold voltage and switch off the semiconductor switching element or diagnose an issue with the semiconductor switching element.

According to one form of the semiconductor fuse, the detection circuit includes a diode that is connected between the detection resistor and the at least one semiconductor switching element.

The diode serves for blocking the HV when the semiconductor switching element is in the blocking state. In the high voltage domain this is desired, but not for applications in the LV domain (low voltage domain).

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a system circuit diagram of a charging system for charging a battery of a battery-electric vehicle according to the present disclosure;

FIG. 2 shows a simplified block circuit diagram of a semiconductor fuse for a battery-electric vehicle according to the present disclosure;

FIG. 3 shows a circuit diagram of a semiconductor fuse according to one form of the present disclosure;

FIG. 4 shows a diagram with example relevant voltage courses of the detection circuit in the case of two different gate voltages according to the present disclosure; and

FIG. 5 shows a circuit diagram of a semiconductor switching element according to another form of the present disclosure.

The Figures are merely schematic representations and serve only for explaining the present disclosure. Identical or functionally identical elements are provided throughout with the same reference numerals.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the following detailed description, reference is made to the accompanying drawings that form a part thereof, and in which specific forms are shown by way of illustration, in which the present disclosure can be explained. It is understood that other forms can also be used, and structural or logical changes can also be undertaken, without deviating from the concept of the present disclosure. The following detailed description is therefore not to be understood in a limiting sense. Furthermore, it is understood that the features of the different examples described herein can be combined with one another if not specifically indicated otherwise.

The aspects are described with reference to the drawings, in which identical reference numerals generally refer to identical elements. The following description provides numerous specific details for explanatory purposes in order to convey a detailed understanding of one or more aspects of the present disclosure. However, one or more aspects can be carried out with a lesser degree of specific details It is understood that other forms can be used, and structural or logical changes can be made, without deviating from the concept of the present disclosure.

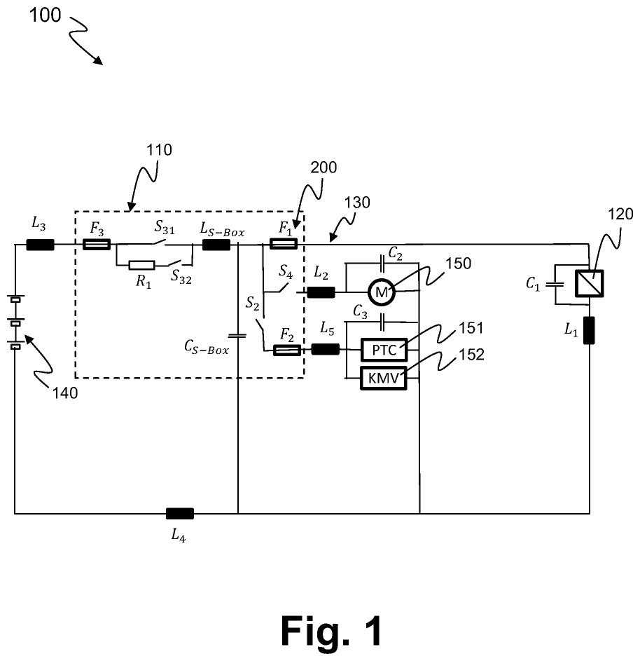

FIG. 1 shows a schematic circuit diagram of a charging system 100 for charging a battery of a battery-electric vehicle.

The charging system 100 comprises electrical and electronic components of the vehicle, shown on the left side, and electrical and electronic components of the charging infrastructure, shown on the right side. The charging infrastructure comprises a charging column 120 for charging the battery 140 of the vehicle, to which a capacitor C₁ is connected in parallel, and an inductance L₁ is connected in series.

On the vehicle side, the electrical and electronic components of the vehicle comprise a battery 140 for powering the vehicle, or an HV storage that is connected in series with the inductance L₃ at a first pole, and an inductance L₄ at a second pole of the battery 140 in the charging current path 130.

An Sbox 110 (switch box or switchbox) is connected in the vehicle in the charging path 130, the Sbox 110 facilitates the battery 140 to be charged. The Sbox 110 is also connected to a traction path as well as to one or more auxiliary consumer paths. The Sbox 110 controls the charging of the battery 140 and the operation of the traction path and the auxiliary consumer paths via the battery 140. Switches for connecting to the charging infrastructure are not shown.

The traction path comprises an electric motor 150, to which a capacitor C₂ is connected in parallel, and an inductance L₂ is connected in series.

The auxiliary consumer paths comprise one or more electronic components connected in parallel, such as, for example, PTC 151 and KMV 152, to which a capacitor C₃ is connected in parallel and an inductance L₅ is connected in series.

The Sbox 110 comprises a fuse F₁ 200 on the charging infrastructure side, which can be a semiconductor fuse 200 as presented in this disclosure. The Sbox 110 further comprises a fuse F₃ on the battery side, and inductance L_{S-Box}, and a circuit with switches S₃₁ and S₃₂ connected in parallel, which are connected in series to the fuse F₁ in the charging current path 130. The fuse F₃ on the battery side can also be the semiconductor fuse 200. A second circuit with switches S₄ and S₂ branches off between the fuse F₁ and the inductance L_{S-Box} in order to connect the traction path and the auxiliary consumer paths to the battery 140 when the vehicle is disconnected from the charging infrastructure. The auxiliary consumer paths are connected to the second circuit via a fuse F₂. The fuse F₂ can also be the semiconductor fuse 200, in which the fuse F₂ then does not serve to disconnect the charging path 130, but rather to disconnect the current path between the battery 140 and the auxiliary consumers 151, 152.

The Sbox 110 further comprises a capacitor C_{S-Box} that is connected in parallel with the charging infrastructure.

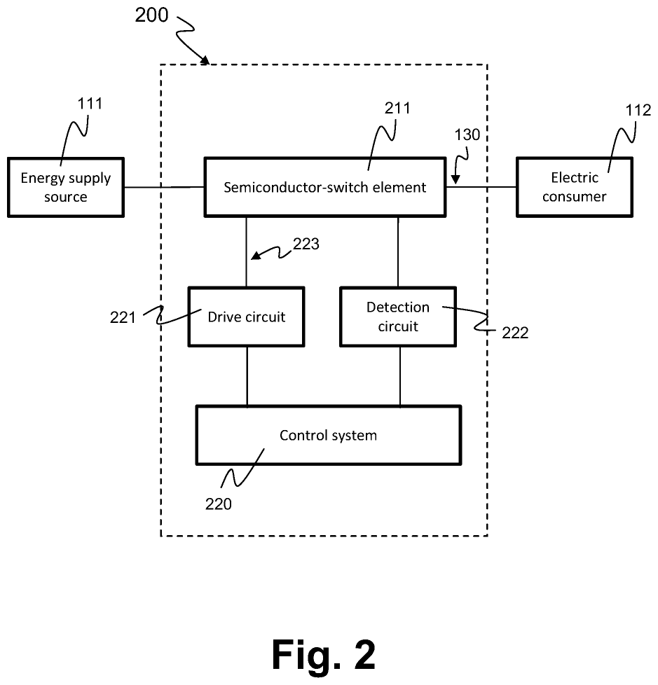

FIG. 2 shows a simplified block circuit diagram of the semiconductor fuse 200 for a battery-electric vehicle.

The semiconductor fuse 200 serves for the secure disconnection of an electrical consumer 112 from an energy supply source 111 for a battery-electric vehicle. This can be, for example, a disconnection of the battery 140 from the charging column 120, as shown in FIG. 1, or it can be a disconnection of the electric motor 150 or of the auxiliary consumers 151, 152 from the battery 140, as shown in FIG. 1.

The semiconductor fuse 200 comprises at least one semiconductor switching element 211 that can be connected between the energy supply source 111 and the electrical consumer 112. In FIG. 2 one such semiconductor switching element 211 is shown, but this can be a plurality of semiconductor switching elements, which are, for example, interconnected with one another in parallel, in order to increase the current carrying capacity of the entire circuit, or also a parallel circuit of semiconductor switching element pairs, in which the switch elements of the respective pairs are oppositely interconnected in series in order to effect a bidirectional blocking.

The at least one semiconductor switching element 211 includes a gate control terminal 212 for controlling a switching on and off of the semiconductor switching element 211 in order to connect the electrical consumer 112 to the energy supply source 111, or to disconnect it from the energy supply source 111. The semiconductor switching element 211 can be, for example, a MOSFET or an IGBT, in which the gate control terminal 212 corresponds to the gate terminal.

The semiconductor fuse 200 comprises a drive circuit 221 that is configured to apply a drive voltage 223 at the gate control terminal 212 of the at least one semiconductor switching element 211, which drive voltage 223 is lower or higher than a prescribed gate threshold voltage of the at least one semiconductor switching element 211.

For the disconnection a lowering of the threshold voltage is desired, and the case to be detected. For other applications, a positive drift of the gate threshold voltage can also be desired. For this purpose, it may be desired to apply a drive voltage 223 with which such a positive drift can be detected, for example, a drive voltage that is higher than the gate threshold voltage.

The prescribed gate threshold voltage is also referred to as the nominal gate threshold voltage and can be read from data sheets of the semiconductor switching elements 211.

A drive voltage 223 can be applied that falls outside a prescribed threshold value range around the prescribed gate threshold voltage, so that a natural fluctuation of the gate threshold voltage does not lead to an unintentional drift detection. An example for such a prescribed threshold value range is the range of −1V/+1V around the prescribed gate threshold voltage.

The prescribed threshold value range can be symmetrical around the prescribed gate threshold voltage, but also asymmetrical, e.g., define a range of −1V/+0.5V, in order to weight a positive deviation of the drift more weakly than a negative deviation, or also vice versa.

The semiconductor fuse 200 comprises a detection circuit 222 that is configured to determine a resistance of the power path 130 of the at least one semiconductor switching element 211, and to detect, based on the resistance of the power path 130, a drift of the gate threshold voltage.

The semiconductor fuse 200 comprises a control system 220 that is configured to indicate, in the event of detecting a drift of the gate threshold voltage, an issue with the at least one semiconductor switching element 211.

The at least one semiconductor switching element 211 can include a drain terminal and a source terminal between which the power path 130 of the at least one semiconductor switching element 211 is formed. The resistance of the power path 130 can thus correspond to a resistance between the drain terminal and the source terminal. The at least one semiconductor switching element 211 can be a field effect transistor, for example, a MOSFET. The at least one semiconductor switching element 211 can be an IGBT.

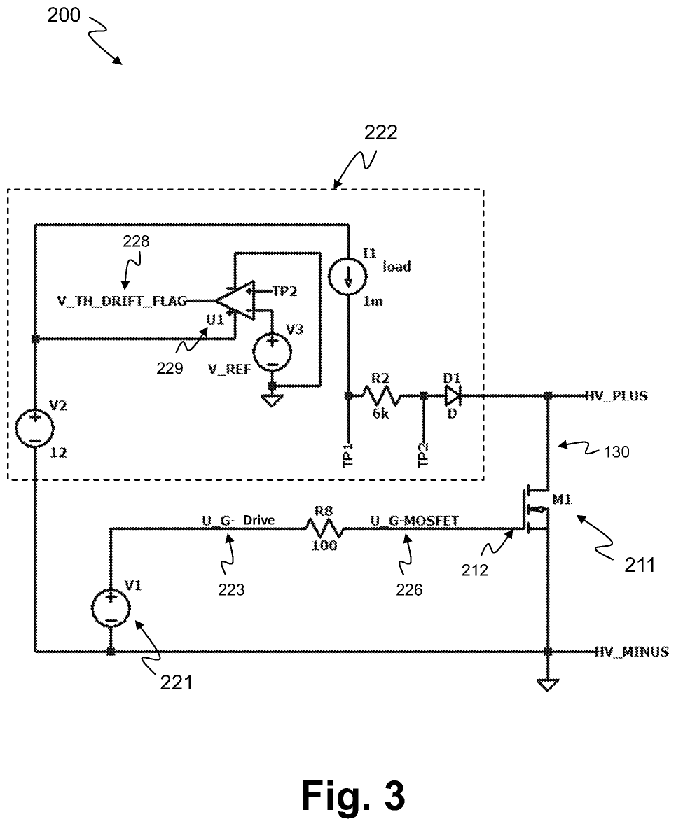

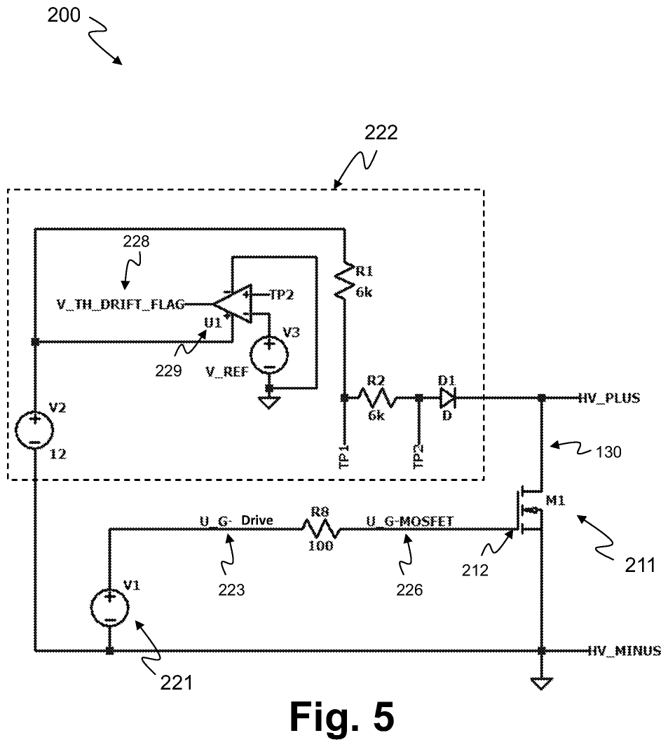

The gate control terminal 212 of the at least one semiconductor switching element 211 can include a gate resistor R8, as shown in FIGS. 3 and 5. The drive circuit 221 can be configured to apply the drive voltage 223 to the gate resistor R8 of the gate control terminal 212. The detection circuit 222 can be configured to determine the resistance of the power path 130 depending on a gate voltage at the gate control terminal 212.

The detection circuit 222 can be connected in parallel with the at least one semiconductor switching element 211, as shown in FIGS. 3 and 5, and configured to impress a current in the power path 130 of the at least one semiconductor switching element 211.

The detection circuit 222 can comprise a detection resistor R2, as shown in FIGS. 3 and 5, and be configured to guide the current impressed in the power path 130 of the at least one semiconductor switching element 211 over the detection resistor R2.

The detection circuit 222 can comprise a voltage source V2 and a current source I1, as shown in FIG. 3, which are connected in series with the detection resistor R2 and configured to impress the current in the power path 130.

Alternatively, the detection circuit 222 can comprise a voltage source V2 and an auxiliary resistor R1, as shown in FIG. 5, which are connected in series with the detection resistor R2, and configured to impress the current in the power path 130.

The detection circuit 222 can be configured to detect a voltage at a first terminal TP1 or a second terminal TP2 of the detection resistor R2, as shown in FIGS. 3 and 5, and to determine, based on the detected voltage, whether the power path 130 is high-resistance.

The detection circuit 222 can comprise a comparator 229, as shown in FIGS. 3 and 5, which is configured to compare the voltage at the first terminal TP1 or the second terminal TP2 of the detection resistor R2 with a reference voltage V3.

The comparator 229 can be configured to set, based on a result of the comparison, a flag 228, as shown in FIGS. 3 and 5, that indicates whether a drift of the gate threshold voltage is present or is not present.

The detection circuit 222 can be configured to indicate a presence of a drift of the gate threshold voltage when the voltage at the first terminal TP1 or the second terminal TP2 of the detection resistor R2 is lower than the reference voltage V3.

FIG. 3 shows a circuit diagram of the semiconductor fuse 200 according to one form.

The semiconductor fuse 200 in FIG. 3 corresponds to the semiconductor fuse 200 shown in FIG. 2, in which in FIG. 3 details are shown for interconnecting the drive circuit 221 and the detection circuit 222 with the semiconductor switching element 211. The semiconductor switching element 211 can be a MOSFET (M1), as shown by way of example in FIG. 3.

The semiconductor switching element 211 includes a gate control terminal 212 for controlling a switching on and off of the semiconductor switching element 211. The gate control terminal 212 corresponds to the gate terminal of the MOSFET M1, as shown in FIG. 3.

The drive circuit 221 is configured to apply a drive voltage (U_G drive) 223 at the gate control terminal 212 of the MOSFET M1 that is lower than a prescribed gate threshold voltage of the MOSFET M1. The drive circuit 221 can be, for example, a voltage source V1.

The detection circuit 222 is configured to determine a resistance of the power path 130 of the MOSFET M1, and to detect, based on the resistance of the power path 130, a drift of the gate threshold voltage.

The semiconductor fuse 200 comprises a control system 220 that is not shown in FIG. 3. The control system 220 is configured to indicate, in the event of detecting the drift of the gate threshold voltage, an issue with the MOSFET M1.

The MOSFET M1 includes a drain terminal and a source terminal, between which the power path 130 of the MOSFET M1 is formed. The resistance of the power path 130 can thus correspond to a resistance between the drain terminal and the source terminal, i.e. an R_{DS}.

The gate control terminal 212 of the MOSFET M1 includes a gate resistor R8. The drive circuit 221 is configured to apply the drive voltage 223 on the gate resistor R8 of the gate control terminal 212. The detection circuit 222 is configured to determine the resistance of the power path 130 depending on a gate voltage at the gate control terminal 212.

The detection circuit 222 is connected in parallel with the MOSFET M1, as can be seen in FIG. 3, and configured to impress a current in the power path 130 of the MOSFET M1.

The detection circuit 222 includes a detection resistor R2, and is configured to guide the current impressed in the power path 130 of the MOSFET M1 via the detection resistor R2.

The detection circuit 222 comprises a voltage source V2 and a current source I1 that are connected in series with the detection resistor R2 and configured to impress the current in the power path 130.

The detection circuit 222 is configured to detect a voltage at the first terminal TP1 or a second terminal TP2 of the detection resistor R2, as shown in FIG. 3, and to determine, based on the detected voltage, whether the power path 130 is high-resistance.

The detection circuit 222 comprises a comparator (U1) 229, which is configured to compare the voltage at the first terminal TP1 or the second terminal TP2 of the detection resistor R2 with a reference voltage V3. In FIG. 3 it is shown that the comparator 229 compares the voltage at the second terminal TP2 of the detection resistor R2 with the reference voltage V3. The reference voltage V3 can be provided, for example, from a reference voltage source V_REF.

The comparator 229 is configured to set, based on a result of the comparison, a flag (V_TH_DRIFT_FLAG) 228 at its output. The flag 228 shows whether a drift of the gate threshold voltage is present or not present.

The detection circuit 222 is configured to indicate a presence of a drift of the gate threshold voltage when the voltage at the first terminal TP1 or the second terminal TP2 of the detection resistor R2 is smaller than the reference voltage V3; here, in FIG. 3 the second terminal TP2 is viewed.

The detection circuit 222 further comprises a diode D1 that is connected between the detection resistor R2 and the at least one semiconductor switching element 211 (M1). The diode D1 is connected to the HV input (HV_PLUS) in the blocking direction and serves for blocking the HV voltage when the semiconductor switching element 211 (M1) is in the blocking state. In the high voltage domain this is desired, but not for applications in the LV domain (low voltage domain).

The functioning of the semiconductor fuse 200 is explained in more detail below.

Before the main fuses, or, depending on the installation location of the dFuse, the second main fuse, unblocks the entire system (see FIG. 1), a voltage is applied at the gate control terminal 212 (gate in the case of a MOSFET) of the semiconductor fuse 200 with the aid of a drive circuit 221 (V1), which voltage is lower than the typical gate threshold voltage 226 (U_G_MOSFET).

With the aid of a detection circuit 222, also referred to as DESAT circuit, it is then checked whether the power path 130 (M1, drain-source) is high-resistance and the power semiconductor is still in the blocking state. This corresponds to the “OK” case.

With the aid of voltage source V2 and current source I1, a current is impressed.

Diode D1 serves for blocking the HV voltage when the semiconductor switching element 211 (M1) is in the blocking state.

If the semiconductor switching element 211 (M1) is high-resistance, the voltage of voltage source V2 is set at first terminal TP1.

Via a comparator circuit (U1) 229 (setting of an error flag 0 corresponds to “not OK;” 1 corresponds to “OK”) this can be evaluated. When U_TP2>V3, then the gate voltage measurement is in order.

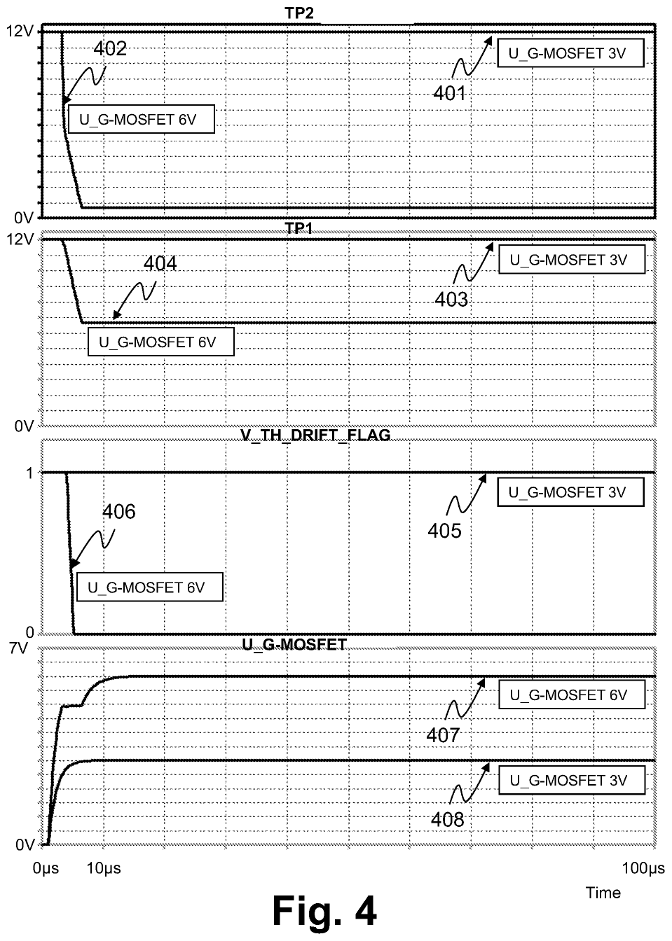

In FIG. 4, the relevant voltage courses of the detection circuit 222 are shown.

If the gate threshold voltage has drifted lower due to a fault or aging, the semiconductor switching element 211 (M1) is no longer blocking, and the voltage at first terminal TP1 is lower than that of the reference voltage source V3.

With the aid of a resistor R2 (R2 may be omitted) and of a measuring point or the second terminal TP2, a statement can be made about the magnitude of the drain-source resistance with the applied test voltage or the drive voltage 223. The drain-source resistance is lower or higher than R2.

If the gate threshold voltage drift detection was successful, the “normal” gate voltage (for example 12V/15V with Si_MOSFETs or 18/21V with SIC-MOSFETs) can be applied, and the entire system can be released by the second main fuse.

The diagnosis described here also functions with a plurality of semiconductors connected in parallel.

Significant features of the solution described here for the gate threshold voltage measurement are the determination of the drain-source resistance and the application of a gate voltage lower than the gate threshold voltage.

Another example is shown in FIG. 5, in which the current source I1 may be omitted. With the example without the current source according to FIG. 5, a resistor is desired (R2); and a second resistor (R1) or even more are optional.

For better readability, filter circuits (for example, RC low-pass filters) and also parasitic line inductances are not shown.

FIG. 4 shows a diagram 400 with example relevant voltage courses of the detection circuit with two different gate voltages at the example of the gate voltages 3V and 6V.

The uppermost diagram shows the voltage course over time at the measurement point or first terminal TP1 (see FIG. 3). The curve 401 shows the “OK” case, in which no voltage drop or a voltage drop does not occur; curve 402 shows the “Not OK” case, in which a voltage drop occurs.

The second diagram from the top shows the voltage course over time at the measuring point or the second terminal TP2 (see FIG. 3). The curve 403 shows the “OK” case, in which no voltage drop or a voltage drop does not occur; the curve 404 shows the “Not OK” case, in which a voltage drop occurs.

The third diagram from the top shows the voltage course over time at the output (V_TH_DRIFT_FLAG) 228 of the comparator (U1) 229 (see FIG. 3). The curve 405 shows the “OK” case, in which the flag remains at 1; the curve 406 shows the “Not OK” case, in which the flag switches to 0 over time.

The fourth diagram from the top shows the voltage course over time at the gate control input or gate (U_G-MOSFET) of the MOSFET M1 (see FIG. 3). The curve 408 shows the “OK” case, in which after a first rising edge, the voltage remains constant; the curve 407 shows the “Not OK” case, in which after the first rising edge, the voltage has a further rising edge over time.

The courses with the gate voltage 3V show the “OK” case, while the courses with the gate voltage 6V indicate the “Not OK” case, at which the MOSFET M1 is switched on.

If the gate threshold voltage has drifted lower due to a fault or aging, the semiconductor switching element 211 (M1) is no longer blocking, and the voltage at measuring point or the first terminal TP1 is lower than that of the reference voltage source V3.

FIG. 5 shows a circuit diagram of a semiconductor fuse 200 according to a further form.

The semiconductor fuse 200 in FIG. 5 corresponds to the semiconductor fuse 200 shown in FIG. 3, in which the current source I1 from FIG. 3 is replaced in FIG. 5 by the resistor R1.

Alternatively to the detection circuit 222 described in FIG. 3, the detection circuit 222 of FIG. 5 can comprise the voltage source V2 and the auxiliary resistor R1, which are connected in series with the detection resistor R2, and are configured to impress the current in the power path 130.

With the semiconductor fuse 200 according to FIG. 5, similar voltage courses occur as shown in FIG. 4.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A semiconductor fuse for a disconnection of an electric consumer from an energy supply source for a battery-electric vehicle, the semiconductor fuse comprising:
at least one semiconductor switching element connectable between the energy supply source and the electric consumer, the at least one semiconductor switching element including a gate control terminal to switch on and off a power path of the at least one semiconductor switching element to connect the electric consumer to the energy supply source or to disconnect the electric consumer from the energy supply source;
a drive circuit configured to apply a drive voltage at the gate control terminal of the at least one semiconductor switching element, the drive voltage is lower or higher than a predetermined gate threshold voltage of the at least one semiconductor switching element;
a detection circuit configured to determine a resistance of the power path of the at least one semiconductor switching element and, based on the resistance of the power path, to detect a drift of the gate threshold voltage; and
a control system configured to indicate an issue with the at least one semiconductor switching element based on the detection of the drift of the gate threshold voltage.

2. The semiconductor fuse according to claim 1, wherein the drive circuit is configured to apply a drive voltage at the gate control terminal of the at least one semiconductor switching element, and the drive voltage falls outside a threshold range associated with the gate threshold voltage.

3. The semiconductor fuse according to claim 1, wherein the at least one semiconductor switching element includes a drain terminal and a source terminal, the power path of the at least one semiconductor switching element is defined between the drain terminal and the source terminal, and the resistance of the power path corresponds to a resistance between the drain terminal and the source terminal.

4. The semiconductor fuse according to claim 1, wherein the gate control terminal of the at least one semiconductor switching element includes a gate resistor, the drive circuit is configured to apply the drive voltage on the gate resistor of the gate control terminal, and the detection circuit is configured to determine the resistance of the power path based on a gate voltage at the gate control terminal.

5. The semiconductor fuse according to claim 1, wherein the detection circuit is connected in parallel with the at least one semiconductor switching element and is configured to impress a current in the power path of the at least one semiconductor switching element.

6. The semiconductor fuse according to claim 5, wherein the detection circuit comprises a detection resistor and is configured to guide the current impressed in the power path of the at least one semiconductor switching element via the detection resistor.

7. The semiconductor fuse according to claim 6, wherein the detection circuit comprises a voltage source and a current source, which are connected in series with the detection resistor and configured to impress the current in the power path.

8. The semiconductor fuse according to claim 6, wherein the detection circuit comprises a voltage source and an auxiliary resistor, which are connected in series with the detection resistor and configured to impress the current in the power path.

9. The semiconductor fuse according to claim 6, wherein the detection circuit is configured to detect a voltage at a first terminal or a second terminal of the detection resistor, and to determine that the power path is high-resistance based on the detected voltage.

10. The semiconductor fuse according to claim 9, wherein the detection circuit comprises a comparator configured to compare the voltage at the first terminal or the second terminal of the detection resistor with a reference voltage.

11. The semiconductor fuse according to claim 10, wherein the comparator is configured to set a flag based on the comparison of the voltage at the first terminal or the second terminal of the detection resistor with the reference voltage that indicates whether a drift of the gate threshold voltage is present or not present.

12. The semiconductor fuse according to claim 10, wherein the detection circuit is configured to indicate the drift of the gate threshold voltage is present based on the voltage at the first terminal or the second terminal of the detection resistor as lower than the reference voltage.

13. The semiconductor fuse according to claim 6, wherein the detection circuit comprises a diode that is connected between the detection resistor and the at least one semiconductor switching element.
